(19) United States
(12) Patent Application Publication
(10) Pub. No.: US 2024/0405030 A1
(43) Pub. Date: Dec. 5, 2024

(54) ARRAY SUBSTRATE AND MANUFACTURING METHOD THEREOF, MASK, AND DISPLAY APPARATUS

(71) Applicants: Chengdu BOE Display Sci-tech Co., Ltd., Chengdu, Sichuan (CN); BOE TECHNOLOGY GROUP CO., LTD., Beijing (CN)

(72) Inventors: Jian WANG, Beijing (CN); Hui TANG, Beijing (CN); Liangliang LI, Beijing (CN); Mengxin RONG, Beijing (CN); Zike SONG, Beijing (CN); Shuangshuang CAI, Beijing (CN)

(21) Appl. No.: 18/701,219

(22) PCT Filed: Sep. 27, 2022
(86) PCT No.: PCT/CN2022/121578

§ 371 Date: Apr. 13, 2024

(51) Int. Cl. H01L 27/12; G03F 1/00; G03F 7/00

(52) U.S. Cl. CPC H01L 27/1248; G03F 1/00; G03F 7/0007; H01L 27/124; H01L 27/1288

(57) ABSTRACT

An array substrate includes a substrate and a via on a side of the substrate. The via includes a first structure and a second structure surrounding the first structure, and the first structure has a light transmittance different from the second structure. An orthographic projection of the first structure on the substrate has a substantially rectangular shape with a plurality of straight sides. An orthographic projection of the second structure on the substrate has a substantially octagonal shape, the second structure includes a plurality of first sub-structures and a plurality of second sub-structures, an orthographic projection of each first sub-structure on the substrate has a strip shape, the first sub-structures are parallel to the straight sides of the first structure in one-to-one correspondence, and an orthographic projection of each second sub-structure on the substrate has a tile shape. Each second sub-structure is between, and connects, two adjacent first sub-structures.

### TECHNICAL FIELD

The present disclosure relates to the field of display technology, and specifically relates to an array substrate and a manufacturing method thereof, a mask, and a display apparatus.

### BACKGROUND

The array substrate includes a substrate, and a plurality of conductive elements on the substrate, e.g., signal lines, pixel electrodes, and the like. The plurality of conductive elements on the substrate are arranged in a plurality of layers, and where the conductive elements of different layers need to be electrically connected, the electrical connection is implemented through vias.

### SUMMARY

Embodiments of the present disclosure provide an array substrate and a manufacturing method thereof, a mask, and a display apparatus.

The present disclosure provides an array substrate, including a substrate and a via on a side of the substrate, wherein: the via includes a first structure and a second structure surrounding the first structure, and the first structure has a light transmittance different from a light transmittance of the second structure;
an orthographic projection of the first structure on the substrate has a substantially rectangular shape with a plurality of straight sides;
an orthographic projection of the second structure on the substrate has a substantially octagonal shape, the second structure includes a plurality of first sub-structures and a plurality of second sub-structures, an orthographic projection of each first sub-structure on the substrate has a strip shape, the first sub-structures are arranged parallel to the straight sides of the first structure in one-to-one correspondence, and an orthographic projection of each second sub-structure on the substrate has a tile shape; and each second sub-structure is between, and connects, two adjacent first sub-structures.

In some embodiments, the orthographic projection of the first structure on the substrate has a right-angle rectangle shape or a rounded rectangle shape.

In some embodiments, the orthographic projection of the first structure on the substrate has a rounded rectangle shape, and includes the plurality of straight sides and an arcuate side connected between adjacent straight sides;
a first angle is formed between connection lines from two ends of the arcuate side to a center of the rounded rectangle, and the first angle is between 5° and 45°; and
the plurality of straight sides includes: two opposite first straight sides and two opposite second straight sides, wherein a ratio of a length of each first straight side to a distance between the two second straight sides is in a range of [0.5, 1); and a ratio of a length of each second straight side to a distance between the two first straight sides is in a range of [0.4, 1).

In some embodiments, the first sub-structures each have a width greater than a width of each of the second sub-structures.

In some embodiments, the first sub-structures have the same light transmittance;
or, the first sub-structures each have a light transmittance higher than a light transmittance of each of the second sub-structures.
the array substrate further includes:
a conductive member on the substrate; and
a connection member on a side of the conductive member away from the substrate, wherein an insulation layer is between the connection member and the conductive member; the via is in the insulation layer, and the connection member is connected to the conductive member through the via; and
wherein the connection member includes: a connection part in the via and a lap joint part on a surface of the insulation layer away from the substrate, and a portion of the surface of the insulation layer away from the substrate opposite to the lap joint part is substantially a flat surface.

In some embodiments, a taper angle of a longitudinal section of the via is less than 30°.

In some embodiments, the taper angle of the longitudinal section of the via is 10° to 29°.

An embodiment of the present disclosure further provides a mask for a method of manufacturing an array substrate, wherein the array substrate is the array substrate in any of the above embodiments, and the mask includes:
a fully light-transmitting area opposite to an area where the first structure of the via is located, wherein the fully light-transmitting area has a plurality of side edges;
a pattern area opposite to an area where the second structure of the via is located, wherein the pattern area surrounds the fully light-transmitting area, and includes a plurality of partially light-transmitting areas spaced apart from each other and a plurality of corner areas, each partially light-transmitting area is opposite to one of the side edges of the fully light-transmitting area, and has a light transmittance lower than a light transmittance of the fully light-transmitting area, and each corner area, as a light-shielding area, is located at a corner position of the fully light-transmitting area.

In some embodiments, each partially light-transmitting area includes at least one light-transmitting slit and at least one light-shielding slit, the light-shielding slit and the light-transmitting slit are alternately arranged in a direction away from the fully light-transmitting area, one of the at least one light-shielding slit is in contact with the fully light-transmitting area, and the light-transmitting slit extends along an extending direction of one of the side edges opposite to the light-transmitting slit.

In some embodiments, in each partially light-transmitting area, a ratio of a width of the light-shielding slit to a width of the light-transmitting slit is between 0.5:1 and 2:1.

In some embodiments, a width of the light-transmitting slit is less than an exposure limit width.

In some embodiments, a width of the light-transmitting slit is between 1 μm and 1.5 μm.

In some embodiments, each partially light-transmitting area includes a plurality of light-transmitting slits and a plurality of light-shielding slits, and for any two light-transmitting slits in a same partially light-transmitting area, the light-transmitting slit farther away from the fully light-transmitting area has a length greater than a length of the light-transmitting slit closer to the fully light-transmitting area.

In some embodiments, the plurality of light-transmitting slits in the pattern area are divided into at least one slit group each including a plurality of the light-transmitting slits, the plurality of light-transmitting slits in a same slit group surround the fully light-transmitting area, and different light-transmitting slits in the same slit group are located on different sides of the fully light-transmitting area, and
for any two adjacent light-transmitting slits in the same slit group, extension lines of edges of the two adjacent light-transmitting slits close to the fully light-transmitting area converge at a first intersection point, and a distance from each of the two adjacent light-transmitting slits to the first intersection point is smaller than or equal to a preset etching offset.

In some embodiments, the mask includes a transparent substrate and a light-shielding layer on the transparent substrate, wherein the light-shielding layer is provided with a first hollowed-out portion corresponding to the fully light-transmitting area, and a second hollowed-out portion corresponding to the partially light-transmitting area; and the second hollowed-out portion is provided with an optical film having a light transmittance lower than a light transmittance of the transparent substrate and higher than a light transmittance of the light-shielding layer.

An embodiment of the present disclosure further provides a method of manufacturing an array substrate, including:
forming a via on a side of a substrate by a lithographic patterning process; wherein the via includes a first structure and a second structure surrounding the first structure, and the first structure has a light transmittance different from a light transmittance of the second structure; an orthographic projection of the first structure on the substrate has a substantially rectangular shape with a plurality of straight sides; an orthographic projection of the second structure on the substrate has a substantially octagonal shape, the second structure includes a plurality of first sub-structures and a plurality of second sub-structures, an orthographic projection of each first sub-structure on the substrate has a strip shape, the first sub-structures are arranged parallel to the straight sides of the first structure in one-to-one correspondence, and an orthographic projection of each second sub-structure on the substrate has a tile shape; and each second sub-structure is between, and connects, two adjacent first sub-structures;
wherein the lithographic patterning process includes an exposure process, in which the mask as described above is used.

In some embodiments, before forming the via on a side of the substrate by the lithographic patterning process, the method further includes:
forming a conductive member on the substrate; and
forming an insulation layer on a side of the conductive member away from the substrate; wherein the via is formed in the insulation layer and exposes the conductive member; and
after forming the via on a side of the substrate by the lithographic patterning process, the method further includes:
providing a connection member on a side of the insulation layer away from the substrate, wherein the connection member is connected to the conductive member through the via; and the connection member includes: a connection part in the via and a lap joint part on a surface of the insulation layer away from the substrate, and a portion of the surface of the insulation layer away from the substrate opposite to the lap joint part is substantially a flat surface.

In some embodiments, the insulation layer includes: a first insulation sublayer and a second insulation sublayer between the first insulation sublayer and the conductive member, wherein the first insulation sublayer is made of a photosensitive material; and
forming the via exposing the conductive member in the insulation layer by the lithographic patterning process includes:
exposing the first insulation sublayer with the mask;
developing the exposed first insulation sublayer to form an intermediate via in the first insulation sublayer at a position corresponding to the via; and
using the developed first insulation sublayer as a mask layer to etch the second insulation sublayer between the first insulation sublayer and the conductive member, to form the via.

An embodiment of the present disclosure further provides a display apparatus, including the array substrate as described above.

### BRIEF DESCRIPTION OF DRAWINGS

Accompanying drawings are provided for further understanding of the present disclosure and constitute a part of the specification. Hereinafter, these drawings are intended to explain the present disclosure together with the following specific implementations, but should not be considered as a limitation of the present disclosure, in which:

FIG. 1 is a plan view of an array substrate according to some embodiments.

FIG. 2 is a schematic sectional view showing connection of conductive elements in different layers according to some embodiments.

FIG. 3 is a schematic diagram illustrating a part of a mask according to some embodiments.

FIG. 4 is a schematic diagram of a via formed with the mask in FIG. 3.

FIG. 5A is a plan view illustrating a part of a mask according to some embodiments of the present disclosure.

FIG. 5B is a schematic diagram showing size indicators of light-transmitting slits in FIG. 5A.

FIG. 6 is a sectional view taken along line A-A′ in FIG. 5A.

FIG. 7 is a plan view illustrating a part of a mask according to further embodiments of the present disclosure.

FIG. 8A is a plan view illustrating a part of a mask according to further embodiments of the present disclosure.

FIG. 8B is a schematic diagram showing size indicators of light-transmitting slits in FIG. 8A.

FIG. 9 is a schematic diagram showing size indicators of an etching offset.

FIG. 10 is a plan view illustrating a part of a mask according to further embodiments of the present disclosure.

FIG. 11 is a sectional view taken along line B-B′ of FIG. 10.

FIG. 12A is a flowchart of a method of manufacturing an array substrate according to some embodiments of the present disclosure.

FIG. 12B is a flowchart of a method of manufacturing an array substrate according to further embodiments of the present disclosure.

FIGS. 13 to 15 are schematic diagrams showing a process of forming a via according to some embodiments of the present disclosure.

FIG. 16 is a plan view of a via according to some embodiments of the present disclosure.

FIG. 17 is a schematic diagram of a first conductive member, a second conductive member and vias corresponding thereto according to some embodiments of the present disclosure.

FIG. 18 shows scanning electron microscope (SEM) images of a first via and a second via according to some embodiments of the present disclosure viewed along a direction perpendicular to the substrate.

FIG. 19 shows scanning electron microscope (SEM) images of a longitudinal section of a via in different embodiments.

FIG. 20 is a schematic diagram of an array substrate according to some embodiments of the present disclosure.

FIG. 21 is a plan view of a first conductive member, a second conductive member, and a connection member according to some embodiments of the present disclosure.

### DETAIL DESCRIPTION OF EMBODIMENTS

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by those of ordinary skill in the art based on the embodiments of the present disclosure described herein without paying any creative effort shall be included in the protection scope of the present disclosure.

Unless otherwise defined, technical or scientific terms used in the present disclosure are intended to have general meanings as understood by those of ordinary skill in the art. The words “first”, “second” and similar terms used in the present disclosure do not denote any order, quantity, or importance, but are used merely for distinguishing different components from each other. Also, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The words “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

An array substrate includes a substrate, and a plurality of conductive elements on the substrate, e.g., signal lines such as gate lines and data lines, pixel electrodes, and the like. The plurality of conductive elements on the substrate are arranged in a plurality of layers, and where the conductive elements of different layers need to be electrically connected, the electrical connection is implemented through vias.

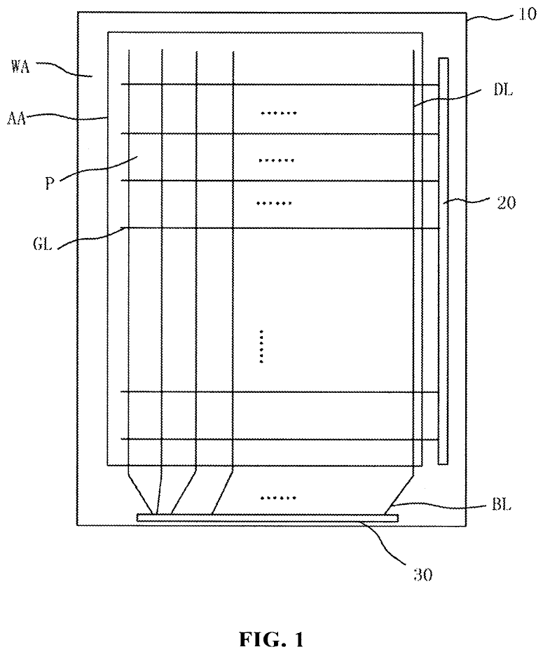

FIG. 1 is a plan view of an array substrate according to some embodiments. As shown in FIG. 1, the array substrate includes: a substrate 10 including a display area AA and a peripheral area WA. The substrate 10 is provided with a plurality of gate lines GL and a plurality of data lines DL intersected with each other to define a plurality of pixel areas P in the display area AA, and structures such as thin film transistors and pixel electrodes are arranged in the pixel areas P. The substrate 10 may be further provided with a gate driver circuit 20 and a source driver circuit 30 both in the peripheral area WA. The gate driver circuit 20 is connected to the gate lines GL to provide scanning signals for the gate lines GL. The gate driver circuit 20 may have a plurality of scanning signal outputs which may be disposed in the same layer as the data lines; and each gate line GL is connected to one of the scanning signal outputs. The source driver circuit 30 is connected to the data lines DL to provide data signals for the data lines DL.

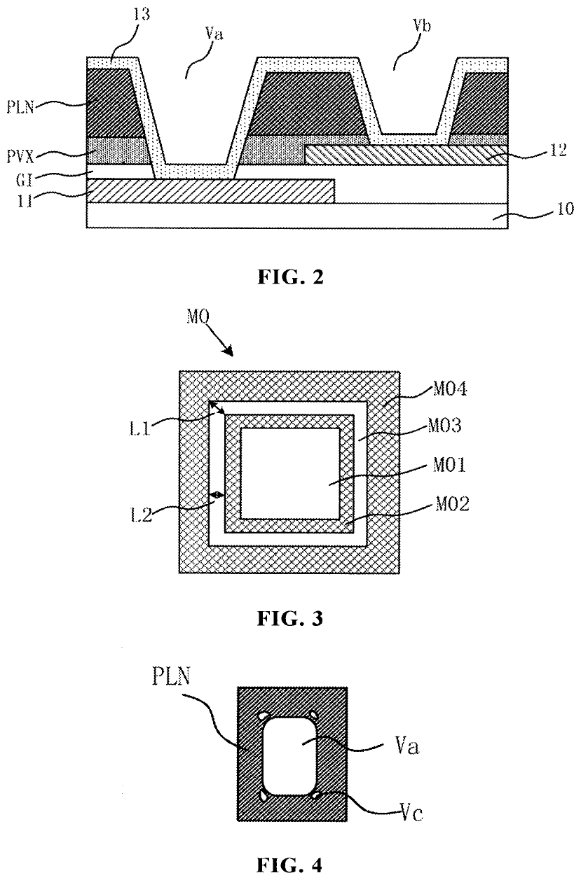

FIG. 2 is a schematic sectional view showing connection of conductive elements in different layers according to some embodiments. As shown in FIG. 2, a first conductive member 11 is provided on the substrate 10, a gate insulation layer GI is provided on a side of the first conductive member 11 away from the substrate 10, a second conductive member 12 is provided on a side of the gate insulation layer GI away from the substrate 10, a passivation layer PVX is provided on a side of the second conductive member 12 away from the substrate 10, a planarization layer PLN is provided on a side of the passivation layer PVX away from the substrate 10, and a connection member 13 is provided on a side of the planarization layer PLN away from the substrate 10. The connection member 13 is connected to the first conductive member 11 through a via Va running through the planarization layer PLN, the passivation layer PVX and the gate insulation layer GI, and is connected to the second conductive member 12 through a via Vb running through the planarization layer PLN and the passivation layer PVX. In one example, the first conductive member 11 is the scanning signal output described above (disposed in the same layer as the data lines), and the second conductive member 12 is the gate line GL. Apparently, the first conductive member 11 and the second conductive member 12 may include other structures. For example, the first conductive member 11 may be the data line DL, and the second conductive member 12 may be a fanout line BL connected to a data driver circuit.

As shown in FIG. 2, the connection member 13 is connected to both the first conductive member 11 and the second conductive member 12 through vias, and to prevent fracture of the connection member 13, a side surface of each via may be set as a gentle slope. FIG. 3 is a schematic diagram illustrating a part of a mask according to some embodiments. A mask M0 as shown in FIG. 3 is used in manufacturing a via. FIG. 3 only shows an area of the mask M0 corresponding to one of the vias (e.g., a via Va), which includes: a first light-transmitting area M01, a first light-shielding area M02 surrounding the first light-transmitting area M01, a second light-transmitting area M03 surrounding the first light-shielding area M02, and a second light-shielding area M04 surrounding the second light-transmitting area M03.

Taking the via Va as an example, a manufacturing process of the via Va includes: exposing the planarization layer PLN with the mask M0 and then developing, to form a sub-via in the planarization layer PLN, and then etching the passivation layer PVX using the planarization layer PLN as a mask layer to form the via Va. During the exposure, the first light-transmitting area M01 of the mask M0 corresponds to a bottom of the via Va, while the second light-shielding area M04 and the second light-transmitting area M03 of the mask correspond to side surfaces of the via Va. Since the second light-transmitting area M03 has a very small width, the planarization layer PLN cannot be fully exposed when light transmits through the second light-transmitting area M03. In other words, the first light-shielding area M02 and the second light-transmitting area M03 as a whole may be used as a translucent area, so that the planarization layer PLN is partially exposed at corresponding positions, and thus the side surface of the via Va forms a slope.

When the mask M0 in FIG. 3 is used for exposure, since the second light-transmitting area M03 has a width L1 at corner positions greater than a width L2 at other positions, the second light-transmitting area M03 has a higher luminous flux at corner positions than at other positions, making the planarization layer more likely to be fully exposed at corners, and after the passivation layer is etched subsequently, an abnormality may occur at positions corresponding to the corners of the second light-transmitting area M03. FIG. 4 is a schematic diagram of a via formed with the mask in FIG. 3. As shown in FIG. 4, in addition to the via Va, additional pinholes Vc may appear in the array substrate at positions close to corners of the via Va (corresponding to corners of the second light-transmitting area M03), and in this case, the subsequently formed connection member 13 tends to be broken at the positions of the pinholes Vc, resulting in an increased impedance of the connection member 13, and higher risks of, for example, a broken circuit and burn.

An embodiment of the present disclosure provides a mask for forming a via on a side of a substrate. The via includes: a first structure and a second structure surrounding the first structure, and the first structure has a light transmittance different from a light transmittance of the second structure. The via may be formed through a lithographic patterning process including an exposure process.

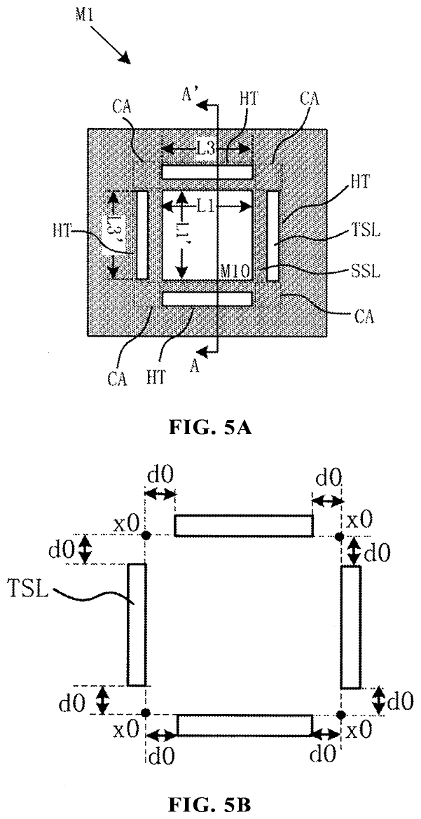

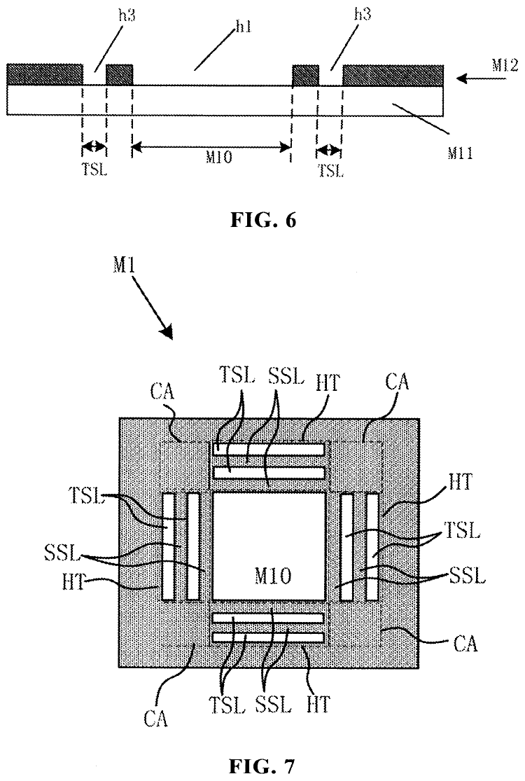

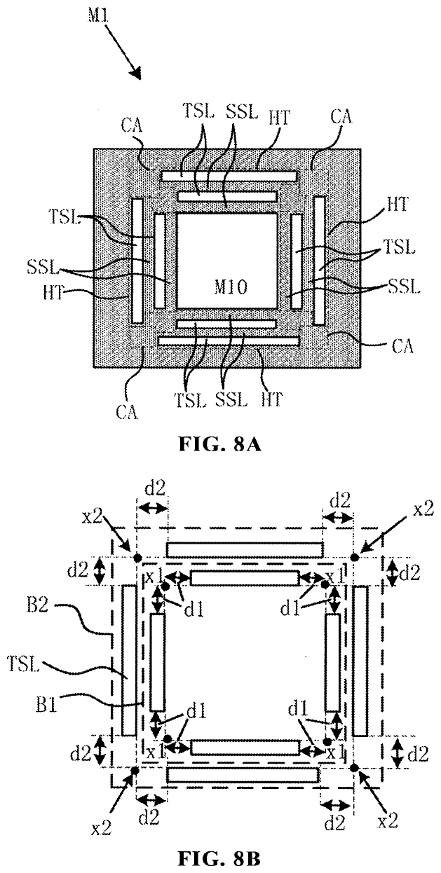

FIG. 5A is a plan view illustrating a part of a mask according to some embodiments of the present disclosure, FIG. 7 is a plan view illustrating a part of a mask according to further embodiments of the present disclosure, and FIG. 8A is a plan view illustrating a part of a mask according to further embodiments of the present disclosure. As shown in FIG. 5A, the mask includes: a fully light-transmitting area M10, and a pattern area. During the exposure process, the fully light-transmitting area M10 is disposed opposite to a position where the first structure is to be formed. The pattern area is disposed opposite to a position where the second structure is to be formed. The fully light-transmitting area M10 may be a polygonal area with a plurality of side edges. The fully light-transmitting area M10 refers to an area through which incident light can completely or substantially completely transmit. For example, the fully light-transmitting area M10 has a light transmittance higher than 85%, or higher than 90%, or higher than 95%, or equal to 100%.

In some examples, the fully light-transmitting area M10 may have a polygonal shape such as a rectangle, a square, a hexagon, an octagon, or the like. Each corner of the polygon may be a corner defined by straight lines, or may be a rounded corner.

The pattern area surrounds the fully light-transmitting area M10, and includes: a plurality of partially light-transmitting areas HT spaced apart from each other and a plurality of corner areas CA. Each of the partially light-transmitting areas HT is disposed opposite to one side edge of the fully light-transmitting area M10. The partially light-transmitting area HT refers to an area where one part of the incident light can transmit through, while the other part of the light cannot transmit through. The partially light-transmitting area HT has a light transmittance lower than a light transmittance of the fully light-transmitting area M10. For example, the partially light-transmitting area HT has a light transmittance between 40% and 70%, or between 50% and 55%, or between 55% and 60%.

Each corner area CA, as a light-shielding area, is located at a corner position of the fully light-transmitting area M10. That is, light impinging onto the corner area CA is completely or substantially completely blocked. For example, the corner area CA has a light transmittance lower than 5% or lower than 8% or equal to 0%. The corner of the fully light-transmitting area M10 refers to a position where two adjacent side edges of the fully light-transmitting area M10 are connected.

It should be noted that the pattern area and the fully light-transmitting area M10 may form a mask area which may be surrounded by light-shielding areas. FIG. 5A shows only one mask area for use in the lithographic patterning process of one via in the array substrate. In practical applications, however, the mask M1 may include a plurality of mask areas, so that the photosensitive material can be exposed at a plurality of positions to form a plurality of vias.

In the mask provided in the embodiments of the present disclosure, the pattern area surrounds the fully light-transmitting area M10, areas of the pattern area opposite to the side edges of the fully light-transmitting area M10 form the partially light-transmitting areas HT, and areas corresponding to corners of the fully light-transmitting area M10 form the light-shielding areas, so that when the photosensitive material is exposed with the mask M1 provided in the embodiments of the present disclosure, the photosensitive material corresponding to the fully light-transmitting area M10 can be fully exposed, and completely removed after development; the photosensitive material corresponding the partially light-transmitting areas HT is partially exposed, and partially removed after development to form a gentle slope; and the photosensitive material corresponding to the corner areas CA is not exposed and reserved after development. In this case, when the developed photosensitive material is used as a mask layer to etch an underlying film layer, a via having a slope can be formed, and since the photosensitive material corresponding to the corner areas CA of the mask M1 is not removed, the pinholes as shown in FIG. 4 will not occur after etching, so that the yield of the subsequently formed connection member can be improved.

As shown in FIGS. 5A and 7, each partially light-transmitting area HT includes at least one light-transmitting slit TSL and at least one light-shielding slit SSL, the light-shielding slit SSL and the light-transmitting slit TSL are alternately arranged in a direction away from the fully light-transmitting area M10, one of the at least one light-shielding slit SSL is in contact with the fully light-transmitting area M10, the light-transmitting slit TSL extends along an extending direction of one of the side edges opposite to the light-transmitting slit TSL, and the light-shielding slit SSL has the same extending direction same as the light-transmitting slit TSL. With the light-shielding slit SSL and the light-transmitting slit TSL alternately arranged, an area where the light-shielding slit SSL and the light-transmitting slit TSL are located as a whole presents a partially light-transmitting effect.

In some embodiments, in each partially light-transmitting area HT, a ratio of a width of the light-shielding slit SSL to a width of the light-transmitting slit TSL is between 0.5:1 and 2:1, so that a gentle slope can be formed after the photosensitive material is exposed by the partially light-transmitting area HT and developed. For example, the ratio of the width of the light-shielding slit SSL to the width of the light-transmitting slit TSL is 0.5:1, or 1:1, or 1.5:1, or 2:1. Preferably, the light-shielding slit SSL and the light-transmitting slit TSL have the same width, so that the photosensitive material is formed with a gentler slope.

In some embodiments, a width of the light-transmitting slit TSL is less than an exposure limit width, where the exposure limit width is an inherent parameter of the lithographic apparatus indicating that: where the width of a certain light-transmitting area or the light-transmitting slit TSL in the mask M1 exceeds the exposure limit width, the photosensitive material can be fully exposed; and where the width of a certain light-transmitting area or the light-transmitting slit TSL on the mask M1 is less than the exposure limit parameter, the photosensitive material cannot be fully exposed.

In some embodiments, the width of the light-transmitting slit TSL is between 1 μm and 1.5 μm. For example, the width of the light-transmitting slit TSL is 1 μm, or 1.2 μm, or 1.4 μm, or 1.5 μm.

In some embodiments, the light-transmitting slit TSL closest to the fully light-transmitting area M10 may have a length equal to the side edge opposite thereto. For example, as shown in FIG. 5A, the fully light-transmitting area M10 has a rectangular shape, lengths of two adjacent side edges are L1 and L1′, respectively, the light-transmitting slit TSL opposite to the side edge with the length L1 has a length L3, and the light-transmitting slit TSL opposite to the side edge with the length L1′ has a length L3′, where L1=L3 and L1′=L3′. Apparently, L1 may be not equal to L3, or L1′ may be not equal to L3′.

In some embodiments, when the partially light-transmitting area HT includes a plurality of light-transmitting slits TSL, as shown in FIG. 7, the light-transmitting slits TSL in the same partially light-transmitting area HT may have the same length.

In other embodiments, when the partially light-transmitting area HT includes a plurality of light-transmitting slits TSL, as shown in FIG. 8A, for any two light-transmitting slits TSL in the same partially light-transmitting area HT, the light-transmitting slit TSL farther away from the fully light-transmitting area M10 has a length greater than a length of the light-transmitting slit TSL closer to the fully light-transmitting area M10.

In some embodiments, the plurality of light-transmitting slits TSL in the pattern area are divided into at least one slit group each including a plurality of light-transmitting slits TSL, the plurality of light-transmitting slits TSL in the same slit group surround the fully light-transmitting area M10, and different light-transmitting slits TSL in the same slit group are located on different sides of the fully light-transmitting area M10. For any two adjacent light-transmitting slits TSL in the same slit group, extension lines of edges of the two adjacent light-transmitting slits TSL close to the fully light-transmitting area M10 converge at a first intersection point, and a distance from each of the two adjacent light-transmitting slits TSL to the first intersection point is smaller than or equal to a preset etching offset.

FIG. 5B is a schematic diagram showing size indicators of light-transmitting slits in FIG. 5A. For example, in FIG. 5A, four light-transmitting slits TSL are arranged around the fully light-transmitting area M10 and form a slit group, extension lines of edges of the two adjacent light-transmitting slits TSL close to the fully light-transmitting area M10 converge at a first intersection point x0, and in the two adjacent light-transmitting slits TSL, a distance from each light-transmitting slit TSL to the first intersection point x0 is d0, which is smaller than a preset etching offset.

For another example, FIG. 8B is a schematic diagram showing size indicators of light-transmitting slits in FIG. 8A, and as shown in FIGS. 8A and 8B, two light-transmitting slits TSL are provided on each side of the fully light-transmitting area M10, and therefore, eight light-transmitting slits TSL in two groups are provided in total. The plurality of light-transmitting slits TSL in the dashed box B1 form a first slit group, the plurality of light-transmitting slits TSL between the dashed box B1 and the dashed box B2 form a second slit group, and the four light-transmitting slits TSL in the first slit group are closer to the fully light-transmitting area M10 than the four light-transmitting slits TSL in the second slit group. In the first slit group, extension lines of edges of the two adjacent light-transmitting slits TSL close to the fully light-transmitting area M10 converge at a first intersection point x1, and in the two adjacent light-transmitting slits TSL, a distance from each light-transmitting slit TSL to the first intersection point is d1, which is smaller than the preset etching offset. In the second slit group, extension lines of edges of the two adjacent light-transmitting slits TSL close to the fully light-transmitting area M10 converge at a first intersection point x2, and in the two adjacent light-transmitting slits TSL, a distance from each light-transmitting slit TSL to the first intersection point x2 is d2, which is smaller than the preset etching offset.

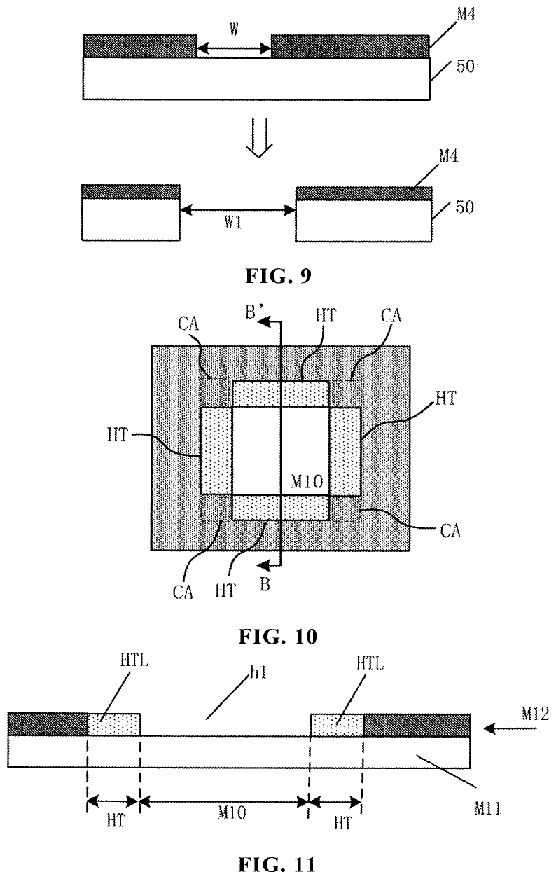

The preset etching offset is determined according to the etching process, and specifically, may be half of an offset between a target etched area and an actual etched area. FIG. 9 is a schematic diagram showing size indicators of an etching offset. As shown in FIG. 9, a film layer 50 to be etched is provided with a mask layer M4 having an opening with a width W (i.e., a width of the target etched area). When the film layer 50 to be etched is etched and an etching gas can etch both the film layer 50 to be etched and the mask layer M4, in addition to longitudinal etching (in which the mask layer M4 is not completely etched off in the longitudinal direction), certain lateral etching will also occur, causing partial etching of both the mask layer M4 and the film layer 50 to be etched in the lateral direction. Finally, the etched area on the film layer 50 to be etched has a width W1 (i.e., a width of the actual etched area). Therefore, W1−W represents a bilateral etching offset, and (W1−W)/2 represents a unilateral etching offset, i.e., the preset etching offset discussed above. It should be noted that FIG. 11 merely shows the etching offset, but not represents the actual topography after etching.

In an embodiment of the present disclosure, for any two adjacent light-transmitting slits TSL in the same slit group, extension lines of edges of the two adjacent light-transmitting slits TSL close to the fully light-transmitting area M10 converge at a first intersection point x1, and a distance from each of the two adjacent light-transmitting slits TSL to the first intersection point x1 is smaller than or equal to the preset etching offset. In this case, after the photosensitive material is exposed with the mask M1, and the developed photosensitive material is used as a mask layer to etch an underlying film layer, a via having a sloped side surface is formed, and the side surface of the via is sloped even at a corner of the via.

FIG. 9 is a sectional view taken along line A-A′ in FIG. 5A. As shown in FIG. 9, in some embodiments, the mask may include a transparent substrate M11, and a light-shielding layer M12 on the transparent substrate M11. The transparent substrate M11 may be a glass substrate or a substrate made of any other transparent material; and the light-shielding layer M12 may be made of a metal material, such as chromium. The light-shielding layer M12 is provided with a first hollowed-out portion h1 corresponding to the fully light-transmitting area M10, and a third hollowed-out portion h3 in an area corresponding to the light-transmitting slit TSL.

FIG. 10 is a plan view illustrating a part of a mask according to further embodiments of the present disclosure, and FIG. 11 is a sectional view taken along line B-B′ of FIG. 10. Like the mask in FIG. 5A, the mask shown in FIG. 10 includes a fully light-transmitting area M10 and a pattern area surrounding the fully light-transmitting area M10. The pattern area includes a plurality of partially light-transmitting areas HT and a plurality of corner areas CA. Different from the mask M1 in FIG. 5A, the partially light-transmitting area HT in FIG. 10 is not provided with the light-transmitting slits TSL and the light blocking slits SSL any more, and instead, all positions are set to have the same transmittance. As shown in FIG. 11, the mask M1 includes a transparent substrate M11, and a light-shielding layer on the transparent substrate M11. The light-shielding layer M12 is provided with a first hollowed-out portion corresponding to the fully light-transmitting area M10, and a second hollowed-out portion in an area corresponding to the partially light-transmitting area HT, where the second hollowed-out portion is provided with an optical film HTL. The optical film HTL has a light transmittance lower than a light transmittance of the fully light-transmitting area M10. For example, the optical film HTL has a light transmittance between 40% and 70%, or between 50% and 55%, or between 55% and 60%, so that the partially light-transmitting area HT has a light transmittance between 40% and 70%, or between 50% and 55%, or between 55% and 60%.

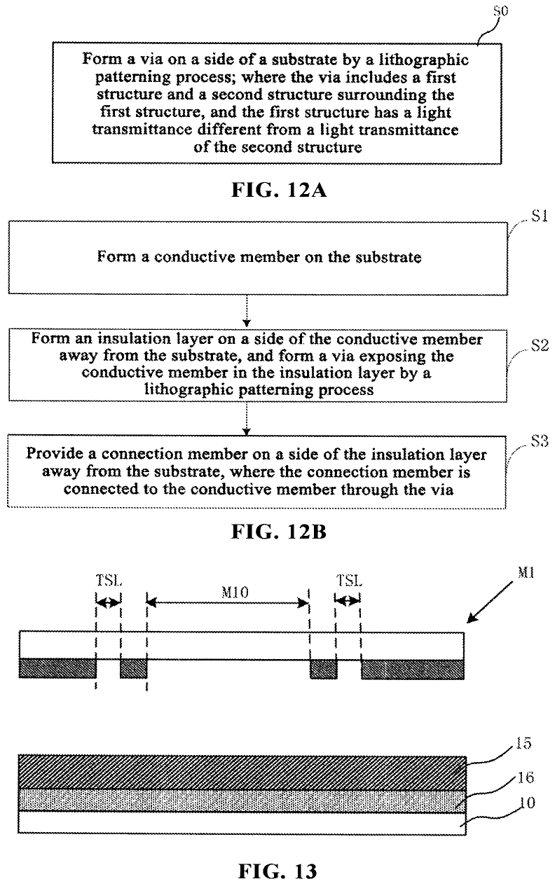

FIG. 12A is a flowchart of a method of manufacturing an array substrate according to some embodiments of the present disclosure. As shown in FIG. 12A, the method of manufacturing an array substrate includes the following step S0.

At S0, forming a via on a side of a substrate by a lithographic patterning process; where the via includes a first structure and a second structure surrounding the first structure, and the first structure has a light transmittance different from a light transmittance of the second structure. An orthographic projection of the first structure on the substrate has a substantially rectangular shape with a plurality of straight sides. An orthographic projection of the second structure on the substrate has a substantially octagonal shape, the second structure includes a plurality of first sub-structures and a plurality of second sub-structures, an orthographic projection of each first sub-structure on the substrate has a strip shape, the first sub-structures are arranged parallel to the straight sides of the first structure in one-to-one correspondence, and an orthographic projection of each second sub-structure on the substrate has a tile shape. Each second sub-structure is located between, and connects, two adjacent first sub-structures.

The lithographic patterning process includes an exposure process, in which the mask according to any of the above embodiments is used.

FIG. 12B is a flowchart of a method of manufacturing an array substrate according to further embodiments of the present disclosure. As shown in FIG. 12B, the method includes the following steps S1 to S3.

At S1, forming a conductive member on the substrate.

At S2, forming an insulation layer on a side of the conductive member away from the substrate, and forming a via exposing the conductive member in the insulation layer by a lithographic patterning process.

At S3, providing a connection member on a side of the insulation layer away from the substrate, where the connection member is connected to the conductive member through the via. The connection member includes: a connection part in the via and a lap joint part on a surface of the insulation layer away from the substrate.

In the exposure process for forming the via, the mask according to any of the above embodiments is used for exposure, and since the corner areas of the mask are light-shielding areas, the pinholes as shown in FIG. 4 will not be generated at positions close to the corners of the via. In other words, a portion of the surface of the insulation layer away from the substrate opposite to the lap joint part is substantially a flat surface.

It should be noted that the substantially flat surface refers to a surface with no pits or protrusions, for example, a surface with a flatness less than 0.25 times, or 0.5 times, or 1 time a thickness of the connection member.

In some embodiments, the insulation layer may be made of a photosensitive material, and during formation of the via, the area where the via is to be formed is exposed with the mask, and then developed, thereby forming the via.

In other embodiments, the insulation layer may include a first insulation sublayer and a second insulation sublayer between the first insulation sublayer and the conductive member, where the first insulation sublayer is made of a photosensitive material. FIGS. 13 to 15 are schematic diagrams showing a process of forming a via according to some embodiments of the present disclosure. As shown in FIGS. 13 to 15, the process of forming the via includes the following steps S21 to S23.

At S21, as shown in FIG. 13, exposing a first insulation sublayer 15 with the mask M1 in the above embodiments. During the exposure, the fully light-transmitting area M10 and the pattern area correspond to an area where the via is to be formed, so that an area of the first insulation sublayer 15 corresponding to the fully light-transmitting area M10 is fully exposed, while an area corresponding to the pattern area is partially exposed. Due to the effect of light diffraction, areas of the first insulation sublayer 15 corresponding to the corner areas CA may also receive a small amount of light and be partially exposed.

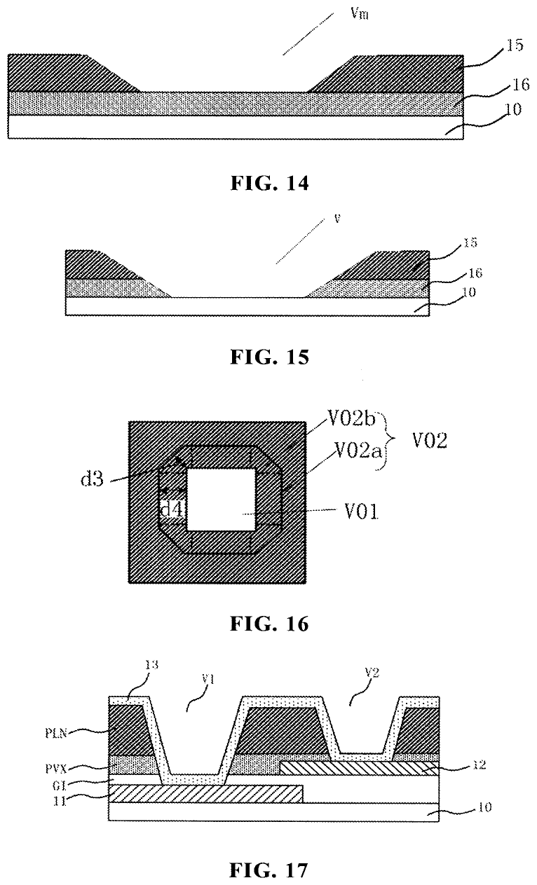

At S22, developing the exposed first insulation sublayer 15 to form an intermediate via Vm in the developed first insulation sublayer 15, where the intermediate via Vm has a sloped side surface, as shown in FIG. 14.

At S23, using the developed first insulation sublayer 15 as a mask layer to etch a second insulation sublayer 16, thereby forming a via V, as shown in FIG. 15. The second insulation sublayer 16 may be etched by dry etching. It should be understood that the etching gas used in the etching process will not affect the conductive member.

FIG. 16 is a plan view of a via according to some embodiments of the present disclosure. As shown in FIG. 16, the via includes: a first structure V01 and a second structure V02 surrounding the first structure V01, and the first structure V01 has a light transmittance different from a light transmittance of the second structure V02. It should be noted that in the embodiments of the present disclosure, the light transmittance of the first structure V01/the second structure V02 refers to brightness of the first structure V01/the second structure V02 viewed through a light microscope along a direction perpendicular to the substrate. The first structure V01 has a higher light transmittance than the second structure V02. That is, the first structure V01 is brighter than the second structure V02 when viewed through a light microscope.

An orthographic projection of the first structure V01 on the substrate has a substantially rectangular shape with a plurality of straight sides. The substantially rectangular orthographic projection refers to an orthographic projection which may have a right-angle rectangle shape or a rounded rectangle shape. Where the orthographic projection has a right-angle rectangle shape, the plurality of straight sides are connected in sequence. Where the orthographic projection has a rounded rectangle shape, the rounded rectangle shape includes not only a plurality of straight sides, but also an arcuate side between two adjacent straight sides.

An orthographic projection of the second structure V02 on the substrate has a substantially octagonal shape, the second structure V02 includes a plurality of first sub-structures V02a and a plurality of second sub-structures V02b, an orthographic projection of each first sub-structure V02a on the substrate is a strip-shaped pattern, and the first sub-structures V02a are arranged parallel to the straight sides of the first structure V01 in one-to-one correspondence. The strip-shaped pattern is a rectangle, and the first sub-structures V02a arranged parallel to the straight sides of the first structure V01 means that longer sides of the first sub-structures V02a are arranged parallel to the straight sides of the first structure V01.

An orthographic projection of each second sub-structure V02b on the substrate has a tile shape, and each second sub-structure V02b is located between, and connects, two adjacent first sub-structures V02a. The tile shape refers to a pattern with two linear connection sides and two non-linear sides, where one linear connection side is connected between first ends of the two non-linear connection sides, and the other linear connection side is connected between second ends of the two non-linear connection sides. The two linear connection sides are shorter sides of the two strip-shaped patterns. The non-linear sides may be arcuate sides or bent sides.

The via has a first opening away from the substrate and a second opening towards the substrate, and a side surface connecting the first opening and the second opening. The orthographic projection of the first structure V01 on the substrate is an orthographic projection of the first opening on the substrate; and the orthographic projection of the second structure V02 on the substrate is an orthographic projection of the second opening on the substrate.

Since areas of the first insulation sublayer 15 corresponding to the corner areas CA and corresponding to the partially light-transmitting areas HT are all partially exposed, and during the etching process, the etching gas may etch both the second insulation sublayer 16 and the first insulation sublayer 15 to a certain extent, the etched side surface of the via forms a continuous and gentle slope.

In addition, since the areas of the first insulation sublayer 15 corresponding to the corner areas CA receive a small amount of light during the exposure process, and during the etching process, the first insulation sublayer and the second insulation sublayer are subjected to both longitudinal and lateral etching, the resulted via may have the topography shown in FIG. 16, which includes the first structure V01 and the second structure V02 as discussed above, where the second structure V02 includes a first sub-structure V02a and a second sub-structure V02b, the first sub-structure V02a has a strip shape, the second sub-structure V02b as a tile shape, and a width d4 of the first sub-structure V02a is greater than a width d3 of the second sub-structure V02b. It should be noted that the width of the first sub-structure V02a is a width of the strip-shaped pattern (i.e., a rectangle); and the width of the second sub-structure V02b refers to a shortest distance between two non-linear sides of the tile-shaped pattern.

In some embodiments, in the via V formed with the mask, the first sub-structure V21 and the second sub-structure V22 have the same light transmittance. That is, the first sub-structure V21 and the second sub-structure V22 have the same brightness when viewed through a light microscope along a direction perpendicular to the substrate. In other embodiments, the first sub-structure V21 has a higher light transmittance than the second sub-structure V22. That is, the first sub-structure V21 is brighter than the second sub-structure V22 when viewed through a light microscope along a direction perpendicular to the substrate.

In practical applications, a plurality of conductive members may be formed simultaneously, and further, a plurality of vias may be formed simultaneously in the array substrate, where each conductive member corresponds to at least one of the vias. For example, the plurality of conductive members may include a plurality of first conductive members and a plurality of second conductive members, and the plurality of vias may include first vias corresponding to the first conductive members and second vias corresponding to the second conductive members.

FIG. 17 is a schematic diagram of a first conductive member, a second conductive member and vias corresponding thereto according to some embodiments of the present disclosure. As shown in FIG. 17, a gate insulation layer GI is provided on a side of the first conductive member 11 away from the substrate 10, a second conductive member 12 is provided on a side of the gate insulation layer GI away from the substrate 10, and a passivation layer PVX and a planarization layer PLN are provided on a side of the second conductive member 12 away from the substrate 10.

In this case, for the first via V1, the insulation layer on the side away from the substrate 10 includes the planarization layer PLN, the passivation layer PVX, and the gate insulation layer GI; the first insulation sublayer corresponding to the first via V1 is the planarization layer PLN, and the second insulation sublayer corresponding to the first via V1 includes the passivation layer PVX, and the gate insulation layer GI. The first insulation sublayer corresponding to the second via V2 is the planarization layer PLN, and the second insulation sublayer corresponding to the second via V2 is the passivation layer PVX.

While the first via V1 and the second via V2 are formed, the planarization layer PLN may be exposed with the mask described above and developed, so that intermediate vias Va are formed at positions where the first via V1 and the second via V2 are to be formed. Thereafter, the passivation layer PVX and the gate insulation layer GI are etched to form the first via V1 and the second via V2.

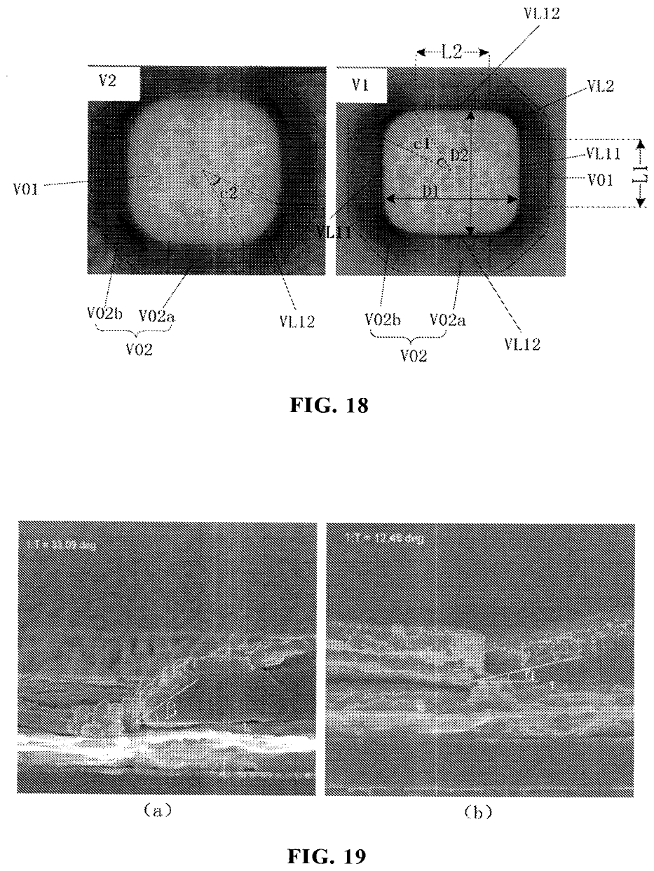

FIG. 18 shows scanning electron microscope (SEM) images of a first via and a second via according to some embodiments of the present disclosure viewed along a direction perpendicular to the substrate, in which mask areas of the mask corresponding to the first via V1 and the second via V2 each have a topography as shown in FIG. 5A. As shown in FIG. 18, the first via V1 and the second via V2 have substantially the same topography, the first via V1 and the second via V2 each include a first structure V01 and a second structure V02, and an orthographic projection of the first structure V01 on the substrate has a rounded rectangle shape.

An orthographic projection of the second structure V02 on the substrate has a substantially octagonal shape. The second structure V02 includes a plurality of first sub-structures V02a and a plurality of second sub-structures V02b, an orthographic projection of each first sub-structure V02a on the substrate is a strip-shaped pattern, and an orthographic projection of each second sub-structure V02b on the substrate is a tile-shaped pattern, and in the first via V1 and the second via V2 in FIG. 18, the tile-shaped pattern of the second sub-structures V02b has: two linear connection sides and two non-linear sides, where one non-linear side closer to the first structure V01 is the arcuate side between two adjacent straight sides in the rounded rectangle shape, and the other non-linear side farther away from the first structure V01 is an arcuate side.

In some embodiments, as shown in FIG. 18, the orthographic projection of the first structure V01 on the substrate has a rounded rectangle shape including a plurality of straight sides and an arcuate side VL2 connected between two adjacent straight sides. The plurality of straight sides includes: two first straight sides VL11 disposed opposite to each other, and two second straight sides VL12 disposed opposite to each other. A ratio of a length L1 of each first straight side VL11 to a distance D2 between the two second straight sides V12 is in a range of [0.5, 1), and a ratio of a length L2 of each second straight side VL12 to a distance D1 between the two first straight sides VL11 is in a range of [0.4, 1). For example, the ratio of the length L1 of each first straight side VL11 to the distance D2 between the two second straight sides V12 is 0.5, or 0.6, or 0.75, or 0.8, or 0.9; and the ratio of the length L2 of each second straight side VL12 to the distance D1 between the two first straight sides VL11 is 0.4, or 0.5, or 0.6, or 0.7, or 0.8.

It should be noted that, in FIG. 18, although only the first straight sides VL11, the second straight sides VL12, and the arcuate sides VL2 in the first via V1 are labeled, the second via V2 also has the first straight sides VL11, the second straight sides VL12 and the arcuate sides VL2 which meet the above size requirements, and thus are not repeated here.

In addition, in the first via V1, a first angle c1 is formed between connection lines from two ends of the arcuate side VL2 of the orthographic projection of the first structure V01, to a center of the rounded rectangle; while in the second via V2, a first angle c2 is formed between connection lines from two ends of the arcuate side VL2 of the orthographic projection of the first structure V01, to a center of the rounded rectangle, where the first angles c1, c2 are both between 5° and 45°. For example, the first angles c1 and c2 are both between 10° and 35°. For example, the first angle c1 is 5°, or 10° or 15°, or 20°, or 25°; and the first angle c1 is 10°, or 15°, or 20°, or 25°, or 30°.

FIG. 19 shows scanning electron microscope (SEM) images of a longitudinal section of a via in different embodiments. The diagram (a) of FIG. 19 is an SEM image of a longitudinal section of a via in a comparative example, and the diagram (b) of FIG. 19 is an SEM image of a longitudinal section of a via according to an embodiment of the present disclosure. While the via according to the embodiment of the present disclosure is formed, a mask area of the mask corresponding to the via has a topography as shown in FIG. 5A. While the via in the comparative example is formed, a mask area of the mask corresponding to the via includes only the fully light-transmitting area M10 shown in FIG. 5A, where the fully light-transmitting area M10 is surrounded by the light-shielding area, and no light-transmitting slit TSL is provided. As shown in FIG. 19, the longitudinal section of the via according to the embodiment of the present disclosure has a taper angle α (i.e., a taper angle of the side surface) of 12°, while the side surface of the via in the comparative example has a taper angle β of 33°. It can be seen that by providing the light-transmitting slits in the fully light-transmitting area M10, the side surface of the via is more gentle, thereby preventing fracture of the subsequently formed connection member. It will be understood that for the via according to the embodiment of the present disclosure, the taper angle of the longitudinal section of the via is the taper angle of the longitudinal section of the second structure V02.

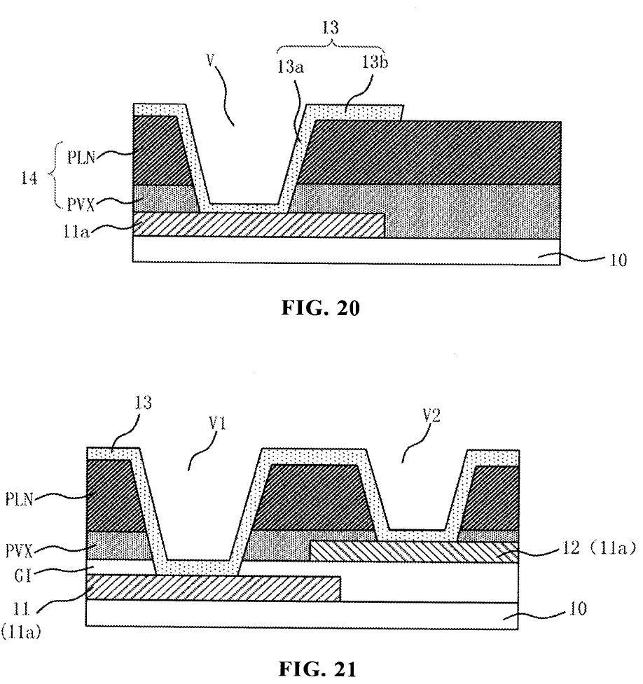

FIG. 20 is a schematic diagram of an array substrate according to some embodiments of the present disclosure, where the array substrate may be manufactured in the method provided in any of the above embodiments. As shown in FIG. 20, the array substrate includes: a substrate 10 and a via V on a side of the substrate 10. In some embodiments, a plan view of the via is as shown in FIG. 16, and the via V includes a first structure V01 and a second structure V02 surrounding the first structure V01. The descriptions about the first structure V01 and the second structure V02 in FIG. 16 may be referred to above and are not repeated here. In other embodiments, a plurality of vias V are disposed on a side of the substrate 10, and the plurality of vias V includes, for example, a first via V1 and a second via V2. The SEM images of longitudinal sections of the first via V1 and the second via V2 are shown in FIG. 18, where the first via V1 and the second via V2 each include a first structure V01 and a second structure V02, which are specifically described above and are not repeated here.

As shown in FIG. 20, the array substrate further includes: a conductive member 11a and a connection member 13 on the substrate 10. The connection member 13 is located on a side of the conductive member 11a away from the substrate 10, an insulation layer 14 is provided between the connection member 13 and the conductive member 11a, the via V is provided in the insulation layer 14, and the connection member 13 is connected to the conductive member 11a through the via V in the insulation layer 14. The manufacturing method of the via V may be referred to the description in the above embodiments.

The connection member 13 includes: a connection part 13a in the via V and a lap joint part 13b on a surface of the insulation layer 14 away from the substrate 10. A portion opposite to the lap joint part 13b on the surface of the insulation layer 14 away from the substrate 10 is substantially a flat surface.

As shown in FIG. 20, the via V has a first opening away from the substrate 10 and a second opening close to the substrate 10, and a side surface connecting the first opening and the second opening. The side surface of the via V is a sloped surface, an orthographic projection of the first opening on the substrate 10 is referred to as a first projection, and an orthographic projection of the second opening on the substrate 10 is referred to as a second projection, and has a substantially rectangular shape. The first projection has a plurality of first edges and a plurality of second edges, the first edges correspond to side edges of the rectangular shape, the second edges correspond to corners of the rectangular shape, and a distance from each second edge to the first projection is less than a distance from each first edge to the first projection.

In some embodiments, a taper angle of a longitudinal section of the via V is less than 30°. Optionally, the taper angle of the longitudinal section of the via V is 10° to 29°. For example, the taper angle of the longitudinal section of the via V is less than 25°, or less than 20°, or less than 15°. For example, the taper angle is 12°.

In some embodiments, the insulation layer 14 includes a first insulation sublayer and a second insulation sublayer between the first insulation sublayer and the conductive member, where the first insulation sublayer is made of a photosensitive material. Apparently, in other embodiments, the first insulation sublayer may be made of a non-photosensitive material, and in this case, when performing the lithographic patterning process, a photoresist layer is firstly formed on the insulation layer. In this case, in the etching step of the lithographic patterning process, a gas capable of etching the photoresist layer may be doped into the etching gas. However, it should be understood that in the etching step, the etching gas should not etch away all the photoresist layer in the longitudinal direction.

In some embodiments, a plurality of conductive members 11a and a plurality of vias are provided on the array substrate, and the plurality of conductive members 11a include: a plurality of first conductive members 11 and a plurality of second conductive members 12. FIG. 21 is a plan view of a first conductive member, a second conductive member, and a connection member according to some embodiments of the present disclosure. As shown in FIG. 21, the first conductive member 11 is located between the layer where the second conductive member 12 is located and the substrate 10, a gate insulation layer GI is provided between the first conductive member 11 and the second conductive member 12, and a passivation layer PVX and a planarization layer PLN are provided on a side of the second conductive member 12 away from the substrate 10, where the planarization layer PLN is located on a side of the passivation layer PVX away from the substrate 10 and made of a photosensitive material.

The insulation layer between the connection member 13 and the first conductive member 11 includes the planarization layer PLN, the passivation layer PVX, and the gate insulation layer GI, and the insulation layer between the connection member and the second conductive member 12 includes the planarization layer PLN and the passivation layer PVX.

Each connection member 13 is connected to one first conductive member 11 through at least one first via V1, and connected to one second conductive member 12 through at least one second via V2. For example, the connection member 13 may be connected to the first conductive member 11 through a plurality of first vias V1, and connected to the second conductive member 12 through a plurality of second vias V2.

An embodiment of the present disclosure further provides a display apparatus, including the array substrate according to any of the above embodiments. The display apparatus may be: an electronic paper, an OLED panel, a mobile phone, a tablet, a television, a monitor, a laptop, a digital album, a navigator or any other product or component having a display function.

It will be appreciated that the above implementations are merely exemplary implementations for the purpose of illustrating the principle of the present disclosure, and the present disclosure is not limited thereto. It will be apparent to those of ordinary skill in the art that various modifications and variations may be made without departing from the spirit or essence of the present disclosure. Such modifications and variations should also be considered as falling into the protection scope of the present disclosure.

1. An array substrate, comprising a substrate and a via on a side of the substrate, wherein: the via comprises a first structure and a second structure surrounding the first structure, and the first structure has a light transmittance different from a light transmittance of the second structure;
an orthographic projection of the first structure on the substrate has a substantially rectangular shape with a plurality of straight sides;
an orthographic projection of the second structure on the substrate has a substantially octagonal shape, the second structure comprises a plurality of first sub-structures and a plurality of second sub-structures, an orthographic projection of each first sub-structure on the substrate has a strip shape, the first sub-structures are arranged parallel to the straight sides of the first structure in one-to-one correspondence, and an orthographic projection of each second sub-structure on the substrate has a tile shape; and each second sub-structure is between, and connects, two adjacent first sub-structures.

2. The array substrate according to claim 1, wherein the orthographic projection of the first structure on the substrate has a right-angle rectangle shape or a rounded rectangle shape.

3. The array substrate according to claim 1, wherein the orthographic projection of the first structure on the substrate has a rounded rectangle shape, and comprises the plurality of straight sides and an arcuate side connected between adjacent straight sides;
a first angle is formed between connection lines from two ends of the arcuate side to a center of the rounded rectangle, and the first angle is between 5° and 45°; and
the plurality of straight sides comprises: two opposite first straight sides and two opposite second straight sides, wherein a ratio of a length of each first straight side to a distance between the two second straight sides is in a range of [0.5, 1); and a ratio of a length of each second straight side to a distance between the two first straight sides is in a range of [0.4, 1).

4. The array substrate according to claim 1, wherein the first sub-structures each have a width greater than a width of each of the second sub-structures.

5. The array substrate according to a claim 1, wherein the first sub-structures have the same light transmittance;
or, the first sub-structures each have a light transmittance higher than a light transmittance of each of the second sub-structures.

6. The array substrate according to a claim 1, wherein the array substrate further comprises:
a conductive member on the substrate; and
a connection member on a side of the conductive member away from the substrate, wherein an insulation layer is between the connection member and the conductive member; the via is in the insulation layer, and the connection member is connected to the conductive member through the via; and
wherein the connection member comprises: a connection part in the via and a lap joint part on a surface of the insulation layer away from the substrate, and a portion of the surface of the insulation layer away from the substrate opposite to the lap joint part is substantially a flat surface.

7. The array substrate according to claim 1, wherein a taper angle of a longitudinal section of the via is less than 30°.

8. The array substrate according to claim 7, wherein the taper angle of the longitudinal section of the via is 10° to 29°.

9. A mask for a method of manufacturing an array substrate, wherein the array substrate is the array substrate according to claim 1, and the mask comprises:
a fully light-transmitting area opposite to an area where the first structure of the via is located, wherein the fully light-transmitting area has a plurality of side edges;
a pattern area opposite to an area where the second structure of the via is located, wherein the pattern area surrounds the fully light-transmitting area, and comprises a plurality of partially light-transmitting areas spaced apart from each other and a plurality of corner areas, each partially light-transmitting area is opposite to one of the side edges of the fully light-transmitting area, and has a light transmittance lower than a light transmittance of the fully light-transmitting area, and each corner area, as a light-shielding area, is located at a corner position of the fully light-transmitting area.

10. The mask according to claim 9, wherein each partially light-transmitting area comprises at least one light-transmitting slit and at least one light-shielding slit, the light-shielding slit and the light-transmitting slit are alternately arranged in a direction away from the fully light-transmitting area, one of the at least one light-shielding slit is in contact with the fully light-transmitting area, and the light-transmitting slit extends along an extending direction of one of the side edges opposite to the light-transmitting slit.

11. The mask according to claim 10, wherein in each partially light-transmitting area, a ratio of a width of the light-shielding slit to a width of the light-transmitting slit is between 0.5:1 and 2:1.

12. The mask according to claim 10, wherein a width of the light-transmitting slit is less than an exposure limit width.

13. The mask according to claim 10, wherein a width of the light-transmitting slit is between 1 μm and 1.5 μm.

14. The mask according to claim 10, wherein each partially light-transmitting area comprises a plurality of light-transmitting slits and a plurality of light-shielding slits, and for any two light-transmitting slits in a same partially light-transmitting area, the light-transmitting slit farther away from the fully light-transmitting area has a length greater than a length of the light-transmitting slit closer to the fully light-transmitting area.

15. The mask according to claim 10, wherein the plurality of light-transmitting slits in the pattern area are divided into at least one slit group each comprising a plurality of the light-transmitting slits, the plurality of light-transmitting slits in a same slit group surround the fully light-transmitting area, and different light-transmitting slits in the same slit group are located on different sides of the fully light-transmitting area, and
for any two adjacent light-transmitting slits in the same slit group, extension lines of edges of the two adjacent light-transmitting slits close to the fully light-transmitting area converge at a first intersection point, and a distance from each of the two adjacent light-transmitting slits to the first intersection point is smaller than or equal to a preset etching offset.

16. The mask according to claim 9, wherein the mask comprises a transparent substrate and a light-shielding layer on the transparent substrate, wherein the light-shielding layer is provided with a first hollowed-out portion corresponding to the fully light-transmitting area, and a second hollowed-out portion corresponding to the partially light-transmitting area; and the second hollowed-out portion is provided with an optical film having a light transmittance lower than a light transmittance of the transparent substrate and higher than a light transmittance of the light-shielding layer.

17. A method of manufacturing an array substrate, comprising:
forming a via on a side of a substrate by a lithographic patterning process; wherein the via comprises a first structure and a second structure surrounding the first structure, and the first structure has a light transmittance different from a light transmittance of the second structure; an orthographic projection of the first structure on the substrate has a substantially rectangular shape with a plurality of straight sides; an orthographic projection of the second structure on the substrate has a substantially octagonal shape, the second structure comprises a plurality of first sub-structures and a plurality of second sub-structures, an orthographic projection of each first sub-structure on the substrate has a strip shape, the first sub-structures are arranged parallel to the straight sides of the first structure in one-to-one correspondence, and an orthographic projection of each second sub-structure on the substrate has a tile shape; and each second sub-structure is between, and connects, two adjacent first sub-structures;
wherein the lithographic patterning process comprises an exposure process, in which the mask according to claim 9 is used.

18. The method according to claim 17, wherein before forming the via on a side of the substrate by the lithographic patterning process, the method further comprises:
forming a conductive member on the substrate; and
forming an insulation layer on a side of the conductive member away from the substrate; wherein the via is formed in the insulation layer and exposes the conductive member; and
after forming the via on a side of the substrate by the lithographic patterning process, the method further comprises:
providing a connection member on a side of the insulation layer away from the substrate, wherein the connection member is connected to the conductive member through the via; and the connection member comprises: a connection part in the via and a lap joint part on a surface of the insulation layer away from the substrate, and a portion of the surface of the insulation layer away from the substrate opposite to the lap joint part is substantially a flat surface.

19. The method according to claim 18, wherein the insulation layer comprises: a first insulation sublayer and a second insulation sublayer between the first insulation sublayer and the conductive member, wherein the first insulation sublayer is made of a photosensitive material; and
forming the via exposing the conductive member in the insulation layer by the lithographic patterning process comprises:
exposing the first insulation sublayer with the mask;
developing the exposed first insulation sublayer to form an intermediate via in the first insulation sublayer at a position corresponding to the via; and
using the developed first insulation sublayer as a mask layer to etch the second insulation sublayer between the first insulation sublayer and the conductive member, to form the via.

20. A display apparatus, comprising the array substrate according to claim 1.
